(19) United States
(12) Patent Application Publication
(10) Pub. No.: US 2026/0293598 A1
(43) Pub. Date: Sep. 24, 2026

(54) STAGE ASSEMBLY, INSPECTION APPARATUS INCLUDING THE STAGE ASSEMBLY, AND INSPECTION METHOD USING THE INSPECTION APPARATUS

(71) Applicant: Samsung Display Co., LTD., Yongin-si (KR)

(72) Inventor: JEHYEON YOON, Yongin-si (KR)

(21) Appl. No.: 19/442,194

(22) Filed: Jan. 7, 2026

(30) Foreign Application Priority Data
Mar. 19, 2025 (KR) 10-2025-0035304

(51) Int. Cl. H10P 72/50; G01N 21/95

(52) U.S. Cl. CPC H10P 72/53; G01N 21/9501

(57) ABSTRACT

A stage assembly includes a stage, a first pin above the stage, the first pin being configured to guide movement of a first substrate, and a second pin above the stage and spaced apart from the first pin in a plan view, the second pin being configured to guide movement of a second substrate.

### CROSS-REFERENCE TO RELATED APPLICATIONS

The present application claims priority to, and the benefit of, Korean Patent Application No. 10-2025-0035304, filed on Mar. 19, 2025, in the Korean Intellectual Property Office, the entire disclosure of which is incorporated herein by reference.

### BACKGROUND

### 1. Field

The present disclosure relates to a stage assembly included in an automatic optical inspection apparatus, an inspection apparatus including the stage assembly, and an inspection method using the inspection apparatus.

### 2. Description of the Related Art

An automatic optical inspection (“AOI”) apparatus may be used to inspect target objects such as a display panel, a printed circuit board, solder balls of a semiconductor package, and/or the like. The AOI apparatus may inspect breakages of the target object, a width between wirings, a length of wirings, positions of elements, attachment states of the elements on a substrate, and/or the like.

The AOI apparatus may capture images of the target object, and may acquire images thereof by moving a stage or a camera in one direction. When the target object is changed, a stage on which the target object is mounted may also be changed. However, when the stage is changed each time the target object is changed, an inspection process may become complicated, and time and cost suitable to inspect the target object may increase.

### SUMMARY

Embodiments of the present disclosure provide a stage assembly for a simplified inspection apparatus.

Embodiments of the present disclosure provide an inspection apparatus including the stage assembly.

Embodiments of the present disclosure provide an inspection method using the inspection apparatus.

A stage assembly according to embodiments includes a stage, a first pin above the stage, the first pin being configured to guide movement of a first substrate, and a second pin above the stage and spaced apart from the first pin in a plan view, the second pin being configured to guide movement of a second substrate.

The first pin may be configured to guide a downward movement of the first substrate, wherein the second pin is configured to guide a downward movement of the second substrate.

A width of the first substrate in a first direction may be less than a width of the second substrate in the first direction.

The first substrate may include a semiconductor wafer substrate, wherein the second substrate includes a polyimide substrate, a quartz substrate, a calcium fluoride substrate, a sodalime glass substrate, or a non-alkali glass substrate.

The first pin may be repeatedly arranged in a first area, wherein the second pin is repeatedly arranged in a second area having a width in a first direction that is greater than a width of the first area in the first direction.

The stage assembly may further include a first chuck configured to fix the first substrate, and a second chuck configured to fix the second substrate and spaced apart from the first chuck in the plan view.

The first chuck and the second chuck may be configured to be moved in a vertical direction and in a horizontal direction.

The first chuck may be provided in plural, wherein the second chuck is provided in plural, and wherein a distance between adjacent ones of the first chucks overlapping with each other in a first direction is less than a distance between adjacent ones of the second chucks overlapping with each other in the first direction.

An inspection apparatus according to embodiments includes a first loading/unloading unit configured to load a first substrate to a stage and to unload the first substrate from the stage, a second loading/unloading unit configured to load a second substrate to the stage and to unload the second substrate from the stage, a first pin above the stage and configured to guide movement of the first substrate, and a second pin above the stage, spaced apart from the first pin in a plan view, and configured to guide movement of the second substrate.

The inspection apparatus may further include a camera configured to image a microchip transferred from a growth substrate onto the first substrate and to image the microchip transferred from the first substrate onto the second substrate.

A width of the first substrate in a first direction may be less than a width of the second substrate in the first direction.

The first substrate may include a semiconductor wafer substrate, wherein the second substrate includes a polyimide substrate, a quartz substrate, a calcium fluoride substrate, a sodalime glass substrate, or a non-alkali glass substrate.

The first pin may be repeatedly arranged in a first area, wherein the second pin is repeatedly arranged in a second area, and wherein a width of the first area in a first direction is less than a width of the second area in the first direction.

The inspection apparatus may further include a first chuck configured to fix the first substrate, and a second chuck configured to fix the second substrate and spaced apart from the first chuck in the plan view.

The first chuck and the second chuck may be configured to be moved in a vertical direction and in a horizontal direction.

The first chuck may be provided in plural, wherein the second chuck is provided in plural, and wherein a distance between adjacent ones of the first chucks overlapping with each other in a first direction is less than a distance between adjacent ones of the second chucks overlapping with each other in the first direction.

An inspection method according to embodiments include transferring a microchip from a growth substrate onto a first substrate, placing the first substrate on a first pin above a stage, lowering the first pin and the first substrate, capturing one or more images of the first substrate and the microchip, transferring the microchip from the first substrate onto a second substrate, placing the second substrate on a second pin above the stage and spaced apart from the first pin in a plan view, lowering the second pin and the second substrate, and capturing one or more images of the second substrate and the microchip.

A width of the first substrate in a first direction may be less than a width of the second substrate in the first direction.

The first substrate may include a semiconductor wafer substrate, wherein the second substrate includes a polyimide substrate, a quartz substrate, a calcium fluoride substrate, a sodalime glass substrate, or a non-alkali glass substrate.

The inspection method may further include moving a first chuck toward the first substrate to fix the first substrate, and moving a second chuck, spaced apart from the first chuck in the plan view, toward the second substrate to fix the second substrate.

A stage assembly according to embodiments may include a stage, a first pin located on the stage, and a second pin located on the stage and spaced apart from the first pin in a plan view. The first pin may guide movement of a first substrate. The second pin may guide movement of a second substrate different from the first substrate.

Accordingly, a target object may be inspected using a single stage assembly regardless of materials included in the substrate located (or, seated) on the stage assembly and a width of the substrate. Accordingly, a configuration of an inspection apparatus may be simplified. In addition, time and cost suitable to inspect the target object may be reduced.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating an inspection apparatus according to embodiments.

FIG. 2 is a plan view illustrating a stage assembly included in the inspection apparatus of FIG. 1.

FIGS. 3, 4, 5, 6, 7, 8, 9, 10, 11, 12, 13, 14, 15, 16, 17, 18, 19, 20, and 21 are front views illustrating an inspection method using the inspection apparatus of FIG. 1.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

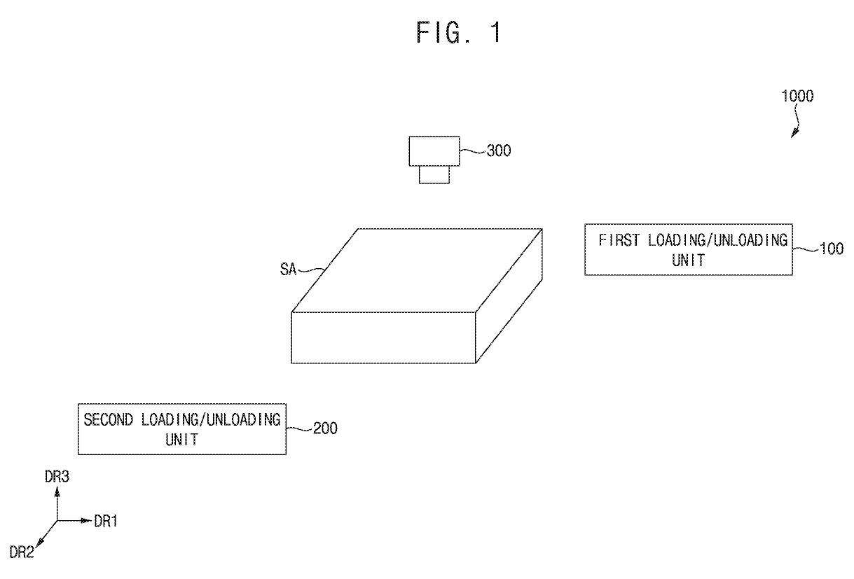

FIG. 1 is a perspective view illustrating an inspection apparatus according to embodiments.

Referring to FIG. 1, an inspection apparatus 1000 according to embodiments may be an automatic optical inspection (“AOI”) apparatus, but this disclosure is not necessarily limited thereto. The inspection apparatus 1000 may include a first loading/unloading unit 100, a second loading/unloading unit 200, a camera 300, and a stage assembly SA.

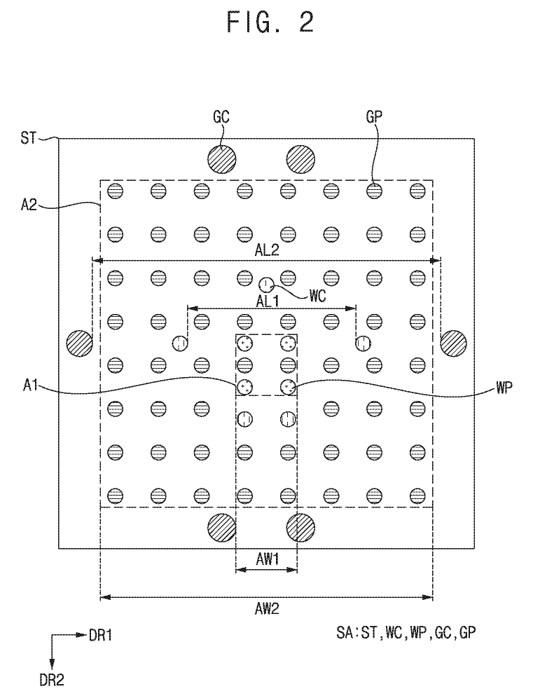

The first loading/unloading unit 100 may load a substrate to the stage assembly SA. For example, the first loading/unloading unit 100 may load the substrate to the stage ST of FIG. 2. The substrate may be located (or, seated) on the stage assembly SA by the first loading/unloading unit 100 (as used herein, “located on” or “seated on” may mean “above”). For example, the substrate may be moved from the first loading/unloading unit 100 onto the stage assembly SA by the first loading/unloading unit 100.

In addition, after inspection of the substrate is completed, the first loading/unloading unit 100 may unload the substrate from the stage assembly SA. For example, the first loading/unloading unit 100 may unload the substrate from the stage. The substrate may be moved from the stage assembly SA to the first loading/unloading unit 100.

The second loading/unloading unit 200 may load the substrate to the stage assembly SA. For example, the second loading/unloading unit 200 may load the substrate to the stage. The substrate may be located (or, seated) on the stage assembly SA by the second loading/unloading unit 200. For example, the substrate may be moved from the second loading/unloading unit 200 onto the stage assembly SA by the second loading/unloading unit 200.

In addition, after inspection of the substrate is completed, the second loading/unloading unit 200 may unload the substrate from the stage assembly SA. For example, the second loading/unloading unit 200 may unload the substrate from the stage. The substrate may be moved from the stage assembly SA to the second loading/unloading unit 200.

In embodiments, the first loading/unloading unit 100 may be located at one side of the stage assembly SA, and the second loading/unloading unit 200 may be located at the other side of the stage assembly SA. For example, as illustrated in FIG. 1, the first loading/unloading unit 100 may be spaced apart from the stage assembly SA in the first direction DR1, and the second loading/unloading unit 200 may be spaced apart from the stage assembly SA in the second direction DR2. However, this disclosure is not necessarily limited thereto, and a position of the first loading/unloading unit 100 and a position of the second loading/unloading unit 200 may vary depending on embodiments. For example, the first loading/unloading unit 100 may be spaced apart from the stage assembly SA in a direction opposite to the first direction DR1. In addition, the second loading/unloading unit 200 may be spaced apart from the stage assembly SA in a direction opposite to the second direction DR2.

In embodiments, the substrate loaded to the stage assembly SA by the first loading/unloading unit 100, and the substrate loaded to the stage assembly SA by the second loading/unloading unit 200, may be different from each other (e.g., may be different respective substrates). For example, a material included in the substrate loaded to the stage assembly SA by the first loading/unloading unit 100, and a material included in the substrate loaded to the stage assembly SA by the second loading/unloading unit 200, may be different from each other. For example, the substrate loaded to the stage assembly SA by the first loading/unloading unit 100 may include a semiconductor wafer substrate. For example, the substrate loaded to the stage assembly SA by the first loading/unloading unit 100 may include a silicon substrate, a silicon carbide substrate, a gallium nitride substrate, and/or the like. These materials may be used alone or in combination with each other. In addition, the substrate loaded to the stage assembly SA by the second loading/unloading unit 200 may include a polyimide substrate, a quartz substrate (e.g., a synthetic quartz substrate, a fluorine-doped quartz substrate, and/or the like), a calcium fluoride substrate, a soda lime glass substrate, a non-alkali glass substrate, and/or the like. These materials may be used alone or in combination with each other.

The camera 300 may image a target object located (or, seated) on the stage assembly SA. For example, the camera 300 may image the substrate loaded to the stage assembly SA by the first loading/unloading unit 100 and the substrate loaded to the stage assembly SA by the second loading/unloading unit 200. Accordingly, the camera 300 may acquire images of each of the substrate loaded to the stage assembly SA by the first loading/unloading unit 100 and the substrate loaded to the stage assembly SA by the second loading/unloading unit 200. The camera 300 may be located on the stage assembly SA. For example, the camera 300 may be spaced apart from the stage assembly SA in a third direction DR3.

In embodiments, the camera 300 may capture images of the substrate loaded onto the stage assembly SA by the first loading/unloading unit 100 and the substrate loaded onto the stage assembly SA by the second loading/unloading unit 200 while the camera 300 moves. However, this disclosure is not necessarily limited thereto, and in one or more other embodiments, the position of the camera 300 may be fixed, and the stage assembly SA may move with respect to the camera 300.

In embodiments, the camera 300 may image the substrate loaded to the stage assembly SA by the first loading/unloading unit 100 and the substrate loaded to the stage assembly SA by the second loading/unloading unit 200 while moving. However, this disclosure is not necessarily limited thereto, and in one or more other embodiments, position of the camera 300 may be fixed and the stage assembly SA may move.

In embodiments, the first direction DR1 and the second direction DR2 crossing the first direction DR1 may be defined. For example, the second direction DR2 may be substantially perpendicular to the first direction DR1. However, this disclosure is not necessarily limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially perpendicular to the plane formed by the first direction DR1 and the second directions DR2. However, this disclosure is not necessarily limited thereto, and the third direction DR3 may form an acute angle or an obtuse angle with the plane formed by the first direction DR1 and the second direction DR2.

FIG. 2 is a plan view illustrating a stage assembly included in the inspection apparatus of FIG. 1.

Referring to FIG. 2, the stage assembly SA may include a stage ST, first pins WP, second pins GP, first chucks WC, and second chucks GC.

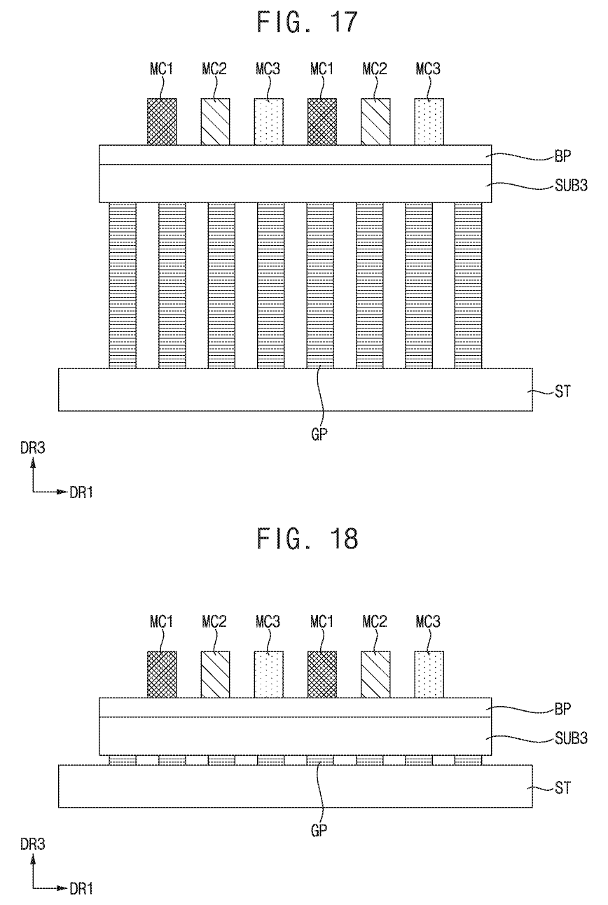

A target object may be located (or, seated) on the stage ST. For example, a first substrate (e.g., a first substrate SUB1 of FIG. 4), a second substrate (e.g., a second substrate SUB2 of FIG. 10), and a third substrate (e.g., a third substrate SUB3 of FIG. 16), to be described later, may be located (or, seated) on the stage ST. In embodiments, the stage ST may have a rectangular parallelepiped shape. However, this disclosure is not necessarily limited thereto, and a shape of the stage ST may vary depending on embodiments. The stage ST may include a lower surface and an upper surface. The upper surface of the stage ST may face the camera (e.g., the camera 300 of FIG. 1), and the lower surface of the stage ST may be opposite to the upper surface. Each of the upper surface and the lower surface of the stage ST may be substantially parallel to the plane defined by the first direction DR1 and the second direction DR2.

The first pins WP may be located on the stage ST. For example, first pin grooves may be formed in the stage ST, and the first pins WP may be inserted into the first pin grooves, respectively. For example, the first pin grooves may be formed in the upper surface of the stage ST, and the first pins WP may be inserted into the first pin grooves, respectively. Each of the first pins WP may move up and down (or, may move vertically) in a corresponding one of the first pin grooves. For example, each of the first pins WP may move in a direction substantially perpendicular to the plane defined by the first direction DR1 and the second direction DR2 in a corresponding one of the first pin grooves. For example, each of the first pins WP may move in the third direction DR3 and in a direction opposite to the third direction DR3 in a corresponding one of the first pin grooves. Accordingly, a degree to which the first pins WP protrude in the third direction DR3 from the upper surface of the stage ST may vary. For example, when the first pins WP move in the third direction DR3, the degree to which the first pins WP protrude in the third direction DR3 from the upper surface of the stage ST may increase, and when the first pins WP move in a direction opposite to the third direction DR3, the degree to which the first pins WP protrude in the third direction DR3 from the upper surface of the stage ST may decrease. In embodiments, each of the first pins WP may have a cylindrical shape. However, this disclosure is not necessarily limited thereto, and a shape of each of the first pins WP may vary depending on embodiments. FIG. 2 may illustrate one example in which the number of the first pins WP is four, but this is merely an example of the number of the first pins WP, and the number of the first pins WP may vary depending on embodiments.

The second pins GP may be located on the stage ST. For example, second pin grooves may be formed in the stage ST, and the second pins GP may be inserted into the second pin grooves, respectively. For example, the second pin grooves may be formed in the upper surface of the stage ST, and the second pins GP may be inserted into the second pin grooves, respectively. Each of the second pins GP may move up and down (or, move vertically) in a corresponding one of the second pin grooves. For example, each of the second pins GP may move in a direction substantially perpendicular to the plane defined by the first direction DR1 and by the second direction DR2 in a corresponding one of the second pin grooves. For example, each of the second pins GP may move in the third direction DR3 and in a direction opposite to the third direction DR3 in a corresponding one of the second pin grooves. Accordingly, a degree to which the second pins GP protrude in the third direction DR3 from the upper surface of the stage ST may vary. For example, when the second pins GP move in the third direction DR3, the degree to which the second pins GP protrude in the third direction DR3 from the upper surface of the stage ST may increase, and when the second pins GP move in a direction opposite to the third direction DR3, the degree to which the second pins GP protrude in the third direction DR3 from the upper surface of the stage ST may decrease. In embodiments, each of the second pins GP may have a cylindrical shape. However, this disclosure is not necessarily limited thereto, and a shape of each of the second pins GP may vary depending on embodiments. The second pins GP may be spaced apart from the first pins WP in a plan view. FIG. 2 may illustrate one example in which the number of the second pins GP is sixty-four, but this is merely an example of the number of the second pins GP, and the number of the second pins GP may vary depending on embodiments.

In embodiments, the first pins WP may be repeatedly arranged in a first area A1. For example, the first area A1 in which the first pins WP are arranged may be defined. The first pins WP may be repeatedly arranged throughout the first area A1. In embodiments, the first area A1 may have a rectangular shape in the plan view. However, this disclosure is not necessarily limited thereto, and a shape of the first area A1 in the plan view may vary depending on embodiments.

In embodiments, the second pins GP may be repeatedly arranged in a second area A2. For example, the second area A2 in which the second pins GP are arranged may be defined. The second pins GP may be repeatedly arranged throughout the second area A2. In embodiments, the second area A2 may have a rectangular shape in the plan view. However, this disclosure is not necessarily limited thereto, and a shape of the second area A2 in the plan view may vary depending on embodiments.

In embodiments, the first area A1 may be located inside the second area A2 (e.g., in plan view). One or more of the second pins GP may also be located in the first area A1. In embodiments, a width AW1 of the first area A1 in the first direction DR1 may be less than a width AW2 of the second area A2 in the first direction DR1. In addition, a width of the first area A1 in the second direction DR2 may be less than a width of the second area A2 in the second direction DR2. For example, an area in which the second pins GP are located may be larger than an area in which the first pins WP are located. For example, the second pins GP may be arranged over a wider area than the first pins WP. In addition, the number of second pins GP may be greater than the number of first pins WP.

The first chucks WC may be located on the stage ST. For example, first chuck grooves may be formed in the stage ST, and the first chucks WC may be inserted into the first chuck grooves, respectively. For example, the first chuck grooves may be formed in the upper surface of the stage ST, and the first chucks WC may be inserted into the first chuck grooves, respectively. Each of the first chucks WC may move vertically and horizontally in a corresponding one of first chuck grooves. In embodiments, a direction of vertical movement may be substantially perpendicular to a direction of a horizontal movement. For example, each of the first chucks WC may move in a direction substantially perpendicular to the plane defined by the first direction DR1 and by the second direction DR2 in a corresponding one of the first chuck grooves. For example, each of the first chucks WC may move in the third direction DR3 and in a direction opposite to the third direction DR3 in a corresponding one of the first chuck grooves. Accordingly, a degree to which the first chucks WC protrude in the third direction DR3 from the upper surface of the stage ST may vary. For example, when the first chucks WC move in the third direction DR3, the degree to which the first chucks WC protrude in the third direction DR3 from the upper surface of the stage ST may increase, and when the first chucks WC move in a direction opposite to the third direction DR3, the degree to which the first chucks WC protrude in the third direction DR3 from the upper surface of the stage ST may decrease. In addition, each of the first chucks WC may also move in an arbitrary direction in the plane defined by the first direction DR1 and the second direction DR2. For example, some (or, one or more) of the first chucks WC may move in (e.g., may effectuate movement in) the second direction DR2 and a direction opposite to the second direction DR2, and some (or, one or more) of the first chucks WC may move in (e.g., may effectuate movement in) the first direction DR1 and a direction opposite to the first direction DR1. In embodiments, each of the first chucks WC may have a cylindrical shape. However, this disclosure is not necessarily limited thereto, and a shape of each of the first chucks WC may vary according to embodiments. FIG. 2 may illustrate one example in which the number of first chucks WC is five, but this is merely an example, and the number of first chucks WC may vary according to embodiments. The first chucks WC may be spaced apart from the first pins WP and the second pins GP in the plan view.

The second chucks GC may be located on the stage ST. For example, second chuck grooves may be formed in the stage ST, and the second chucks GC may be inserted into the second chuck grooves, respectively. For example, the second chuck grooves may be formed in the upper surface of the stage ST, and the second chucks GC may be inserted into the second chuck grooves, respectively. Each of the second chucks GC may move vertically and horizontally in a corresponding one of the second chuck grooves. In embodiments, a direction of vertical movement may be substantially perpendicular to a direction of a horizontal movement. For example, each of the second chucks GC may move in a direction substantially perpendicular to the plane defined by the first direction DR1 and the second direction DR2 in a corresponding one of the second chuck grooves. For example, each of the second chucks GC may move in the third direction DR3 and a direction opposite to the third direction DR3 in a corresponding one of the second chuck grooves. Accordingly, a degree to which the second chucks GC protrude in the third direction DR3 from the upper surface of the stage ST may vary. For example, when the second chucks GC move in the third direction DR3, the degree to which the second chucks GC protrude in the third direction DR3 from the upper surface of the stage ST may increase, and when the second chucks GC move in a direction opposite to the third direction DR3, the degree to which the second chucks GC protrude in the third direction DR3 from the upper surface of the stage ST may decrease. In addition, each of the second chucks GC may also move in an arbitrary direction in the plane defined by the first direction DR1 and the second direction DR2. For example, some (or, one or more) of the second chucks GC may move in (e.g. may effectuate movement in) the second direction DR2 and a direction opposite to the second direction DR2, and some (or, one or more) of the second chucks GC may move in (e.g., may effectuate movement in) the first direction DR1 and a direction opposite to the first direction DR1. In embodiments, each of the second chucks GC may have a cylindrical shape. However, this disclosure is not necessarily limited thereto, and a shape of each of the second chucks GC may vary according to embodiments. FIG. 2 may illustrate one example in which the number of second chucks GC is six, but this is merely an example, and the number of second chucks GC may vary according to embodiments. The second chucks GC may be spaced apart from the first pins WP, the second pins GP, and the first chucks WC in the plan view.

In embodiments, a separation distance AL1 in the plan view between the first chucks overlapping each other in the first direction DR1 among the first chucks WC may be less than a separation distance AL2 in the plan view between the second chucks overlapping each other in the first direction DR1 among the second chucks GC. The separation distance AL1 in the plan view may be a separation distance in the plan view between ends of the first chucks overlapping each other in the first direction DR1 among the first chucks WC. In addition, the separation distance AL2 in the plan view may be a separation distance in the plan view between ends of the second chucks overlapping each other in the first direction DR1 among the second chucks GC.

In embodiments, the first chucks WC may be located inside the second area A2, and the second chucks GC may be located outside the second area A2. For example, the stage ST may include a first side, a second side, a third side, and a fourth side in the plan view, and some of the second chucks GC may be located adjacent to the first side, some of the second chucks GC may be located adjacent to the second side, some of the second chucks GC may be located adjacent to the third side, and some of the second chucks GC may be located adjacent to the fourth side.

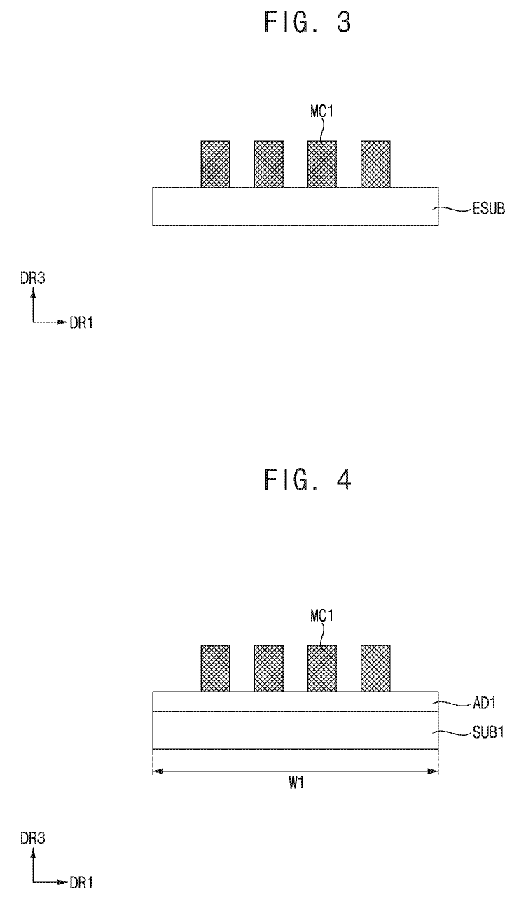

The inspection apparatus (e.g., the inspection apparatus 1000 of FIG. 1) according to embodiments may inspect a target object during a manufacturing process of a display device. For example, the inspection apparatus may inspect a target object during a manufacturing process of a display device including micro-LED chips. Hereinafter, an inspection method using the inspection apparatus is described in detail with reference to FIGS. 3, 4, 5, 6, 7, 8, 9, 10, 11, 12, 13, 14, 15, 16, 17, 18, 19, 20, and 21.

FIGS. 3, 4, 5, 6, 7, 8, 9, 10, 11, 12, 13, 14, 15, 16, 17, 18, 19, 20, and 21 are front views illustrating an inspection method using the inspection apparatus of FIG. 1.

Referring to FIG. 3, first microchips MC1 may be formed on a growth substrate ESUB. The growth substrate ESUB may be an epitaxial substrate. For example, the growth substrate ESUB may include a silicon substrate, a silicon carbide substrate, a gallium nitride substrate, a sapphire substrate, and/or the like. These materials may be used alone or in combination with each other. For example, the growth substrate ESUB may be a sapphire substrate.

Each of the first microchips MC1 may include a first semiconductor layer, a first active layer, and a second semiconductor layer.

In embodiments, the first semiconductor layer may include an n-type semiconductor layer. The first semiconductor layer may include a semiconductor material such as GaN, InAlGaN, AlGaN, InGaN, AlN, InN, and/or the like, and may include an n-type semiconductor layer doped with a first conductive dopant (e.g., an n-type dopant) such as Si, Sn, Te, Se, S, O, Ti, Ge, and/or the like. However, this disclosure is not necessarily limited thereto, and the first semiconductor layer may include a p-type semiconductor layer.

The first active layer may include a single-well structure, a multiple-well structure, a single quantum well structure, a multiple quantum well structure, a quantum dot structure, or a quantum wire structure. For example, the first active layer may include a multiple quantum well structure. In this case, the first active layer may include a structure in which well layers and barrier layers are alternately stacked. The well layer may include InGaN, and the barrier layer may include GaN or AlGaN, but this disclosure is not necessarily limited thereto.

In embodiments, the second semiconductor layer may include a p-type semiconductor layer. For example, the second semiconductor layer may include a semiconductor material such as GaN, InAlGaN, AlGaN, InGaN, AlN, InN, and/or the like, and may include a p-type semiconductor layer doped with a second conductive dopant (e.g., a p-type dopant) such as Zn, Fe, Mg, Be, Cd, Ag, C, Hg, Li, Ca, and/or the like. For example, the second semiconductor layer may include a GaN semiconductor material doped with the second conductive dopant. However, this disclosure is not necessarily limited thereto, and the second semiconductor layer may include an n-type semiconductor layer.

Referring to FIGS. 3 and 4, the first microchips MC1 may be transferred from the growth substrate ESUB onto the first substrate SUB1. For example, a first adhesive layer AD1 may be formed on the first substrate SUB1, and the first microchips MC1 may be transferred onto the first adhesive layer AD1. The first adhesive layer AD1 may include an optical clear resin (“OCA”), an optical clear resin (“OCR”), or a pressure sensitive adhesive (“PSA”).

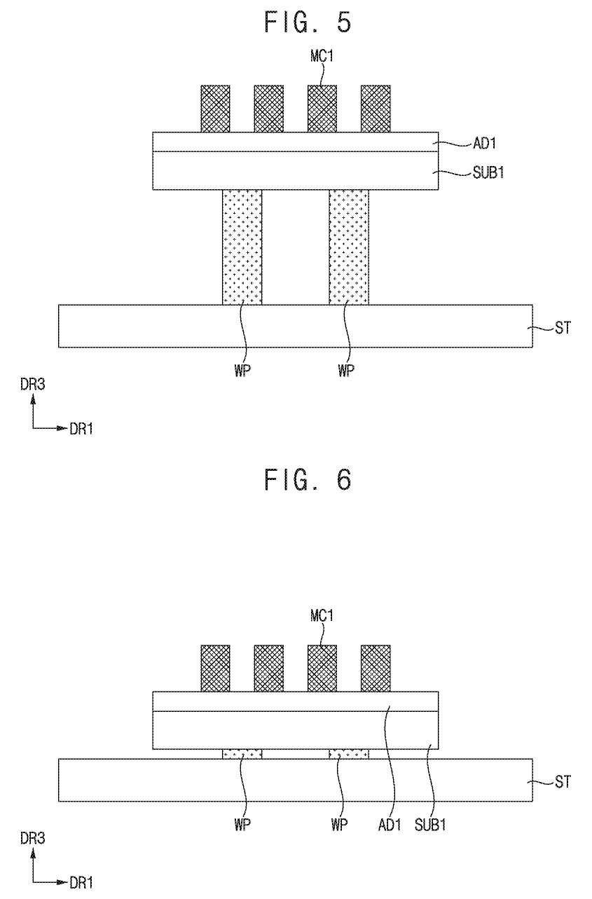

Referring to FIG. 5, a first substrate SUB1 may be located (or, seated) on the stage assembly (e.g., the stage assembly SA of FIG. 1). In embodiments, the first substrate SUB1 may include a semiconductor wafer substrate. For example, the first substrate SUB1 may include a silicon substrate, a silicon carbide substrate, a gallium nitride substrate, and/or the like. These materials may be used alone or in combination with each other. As described with reference to FIG. 2, the substrate loaded to the stage assembly by the first loading/unloading unit (e.g., the first loading/unloading unit 100 of FIG. 2) may include a semiconductor wafer substrate. Accordingly, the first substrate SUB1 may be loaded to the stage assembly by the first loading/unloading unit. In embodiments, the first substrate SUB1 may be a carrier wafer substrate.

In embodiments, the first substrate SUB1 may be located (or, seated) on the first fins WP. For example, after the first fins WP move up (or, move in the third direction DR3), the first substrate SUB1 may be located (or, seated) on the first fins WP. For example, the first substrate SUB1, the first adhesive layer AD1, and the first microchips MC1 may be located (or, seated) on the first fins WP.

Referring to FIG. 6, the first fins WP may guide movement of the first substrate SUB1. For example, the first fins WP may guide a downward movement of the first substrate SUB1. As described above, the first fins WP may move down (or, may move in a direction opposite to the third direction DR3). As the first fins WP move down, the first substrate SUB1, the first adhesive layer AD1, and the first microchips MC1 located (or, seated) on the first fins WP may move down.

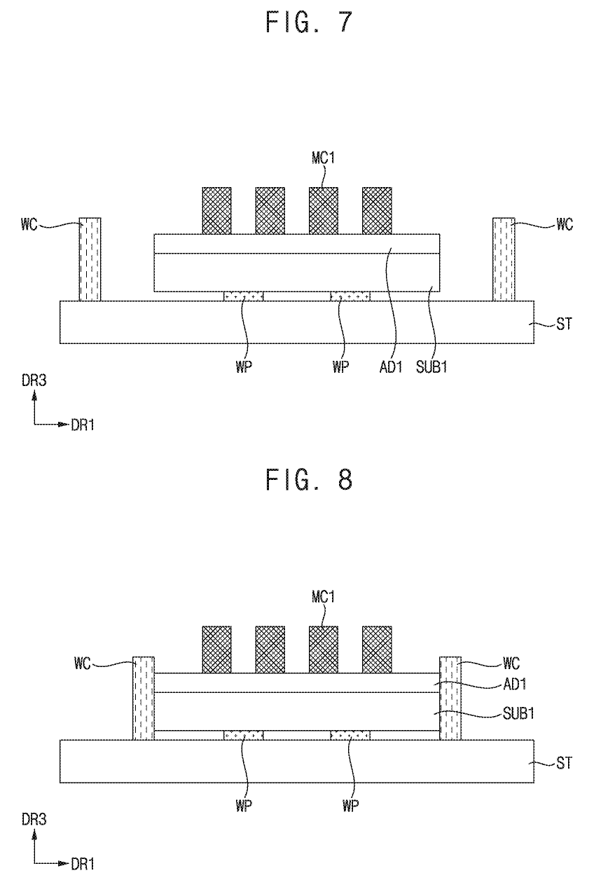

Referring to FIG. 7, the first chuck WC may move up (or, may move in the third direction DR3).

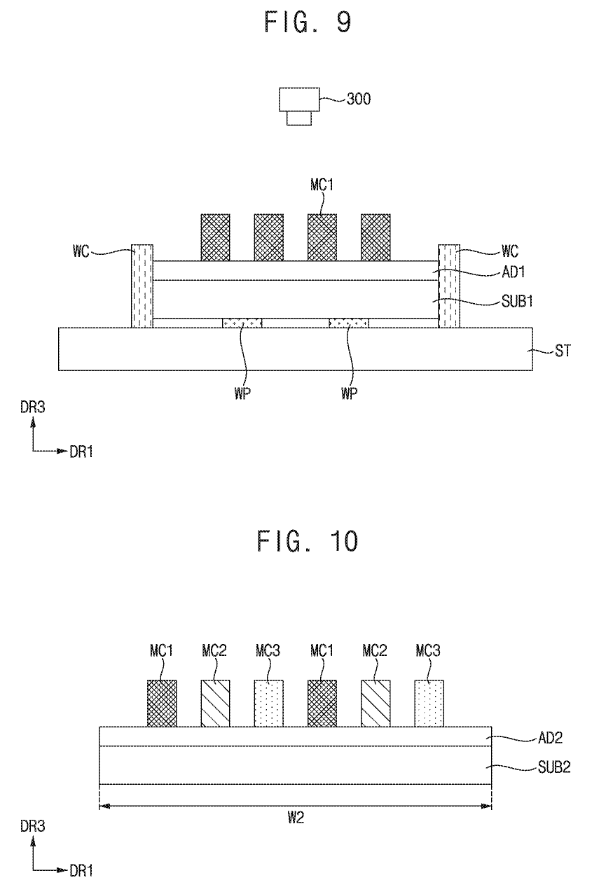

Referring to FIG. 8, the first chucks WC may move in an arbitrary direction in the plane defined by the first direction DR1 and the second direction DR2. For example, the first chucks WC may move toward the first substrate SUB1. Accordingly, the first chucks WC may be located in close contact with the first substrate SUB1. For example, the first chucks WC may contact a side surface of the first substrate SUB1. Accordingly, the first chucks WC may fix the first substrate SUB1. For example, the first chucks WC may fix a position of the first substrate SUB1 on the stage ST. In addition, the first chucks WC may fix the first substrate SUB1 so that the first substrate SUB1 does not rotate on the stage ST. Accordingly, the camera (e.g., the camera 300 of FIG. 9) may image the first substrate SUB1 and the first microchips MC1 suitably and without error.

Referring to FIG. 9, the camera 300 may image the first substrate SUB1. For example, the camera 300 may image the first microchips MC1 located on the first substrate SUB1. Through the camera 300, it may be determined whether the first microchips MC1 are damaged, whether the first microchips MC1 are properly transferred onto the first substrate SUB1, and how the first microchips MC1 are arranged. For example, the camera 300 may acquire visual information about the first microchips MC1.

After acquiring visual information about the first microchips MC1 through the camera 300, the first substrate SUB1 may be unloaded from the stage assembly by using the first loading/unloading unit. For example, the first substrate SUB1, the first adhesive layer AD1, and the first microchips MC1 may be unloaded from the stage assembly by using the first loading/unloading unit.

Referring to FIG. 10, the first microchips MC1, second microchips MC2, and third microchips MC3 may be transferred onto a second substrate SUB2. For example, the first microchips MC1 may be transferred from the first substrate (e.g., the first substrate SUB1 of FIG. 9) onto the second substrate SUB2. Referring to FIG. 3, a method of forming the first microchips MC1 has been described, but this disclosure is not necessarily limited thereto, and the second microchips MC2 and the third microchips MC3 may be formed by a method substantially the same as the method of forming the first microchips MC1. In addition, referring to FIGS. 4, 5, 6, 7, 8, and 9, although a method of inspecting the first microchips MC1 after the first microchips MC1 are transferred onto the first substrate has been described, this disclosure is not necessarily limited thereto, and the second microchips MC2 and the third microchips MC3 may be transferred onto the first substrate, and then may be inspected by a method substantially the same as the method of inspecting the first microchips MC1. A second adhesive layer AD2 may be formed on the second substrate SUB2, and each of the first microchips MC1, the second microchips MC2, and the third microchips MC3 may be transferred onto the second adhesive layer AD2.

In embodiments, the first microchips MC1, the second microchips MC2, and the third microchips MC3 may emit light having different respective wavelengths. For example, each of the first microchips MC1 may emit red light, each of the second microchips MC2 may emit green light, and each of the third microchips MC3 may emit blue light, but this disclosure is not necessarily limited thereto.

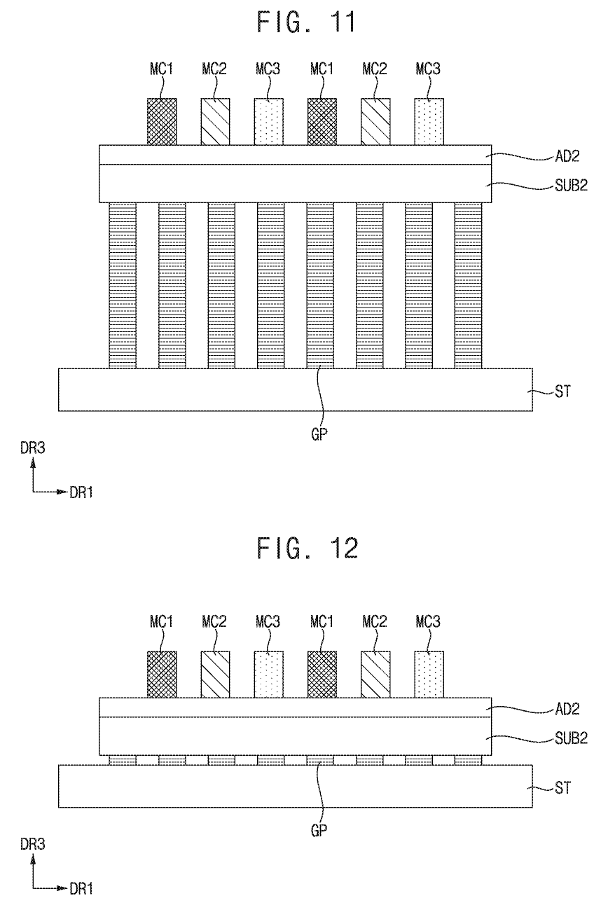

Referring to FIG. 11, the second substrate SUB2 may be located (or, seated) on the stage assembly. In embodiments, the second substrate SUB2 may include a polyimide substrate, a quartz substrate (e.g., a synthetic quartz substrate, a fluorine-doped quartz substrate, and/or the like), a calcium fluoride substrate, a soda lime glass substrate, a non-alkali glass substrate, and/or the like. These materials may be used alone or in combination with each other. As described with reference to FIG. 2, the substrate loaded to the stage assembly by the second loading/unloading unit (e.g., the second loading/unloading unit 200 of FIG. 2) may include a polyimide substrate, a quartz substrate (e.g., a synthetic quartz substrate, a fluorine-doped quartz substrate, and/or the like), a calcium fluoride substrate, a soda lime glass substrate, a non-alkali glass substrate, and/or the like. Accordingly, the second substrate SUB2 may be loaded to the stage assembly by the second loading/unloading unit.

However, this disclosure is not necessarily limited thereto, and in one or more other embodiments, the second substrate SUB2 may include a semiconductor wafer substrate. In this case, the second substrate SUB2 may be loaded to the stage assembly by the first loading/unloading unit.

In embodiments, the second substrate SUB2 may be located (or, seated) on the second pins GP. For example, after the second pins GP move up (or, move in the third direction DR3), the second substrate SUB2 may be located (or, seated) on the second pins GP. For example, the second substrate SUB2, the second adhesive layer AD2, the first microchips MC1, the second microchips MC2, and the third microchips MC3 may be located (or, seated) on the second pins GP.

Referring to FIG. 12, the second pins GP may guide a movement of the second substrate SUB2. For example, the second pins GP may guide a downward movement of the second substrate SUB2. As described above, the second pins GP may move down (or, move in a direction opposite to the third direction DR3). As the second pins GP move down, the second substrate SUB2, the second adhesive layer AD2, the first microchips MC1, the second microchips MC2, and the third microchips MC3, located (or, seated) on the second pins GP, may move down.

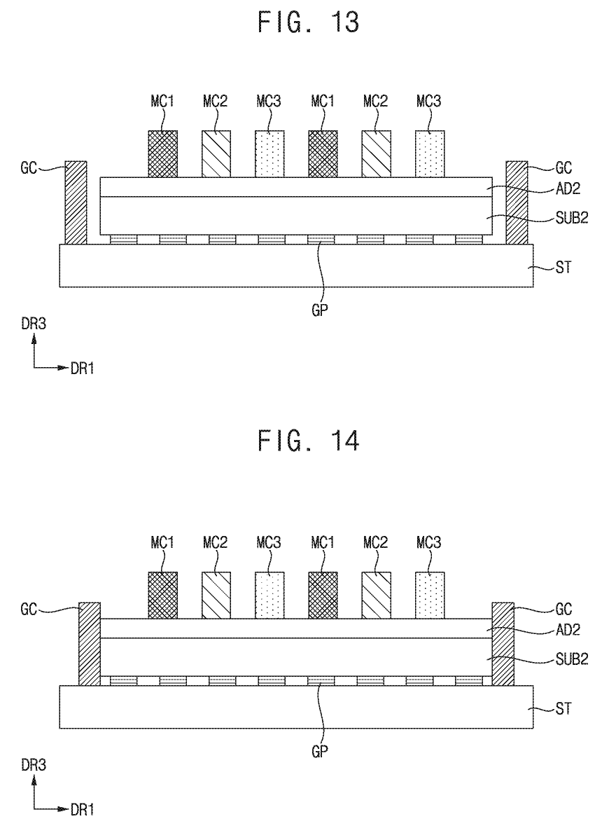

Referring to FIG. 13, the second chucks GC may move up (or move in the third direction DR3).

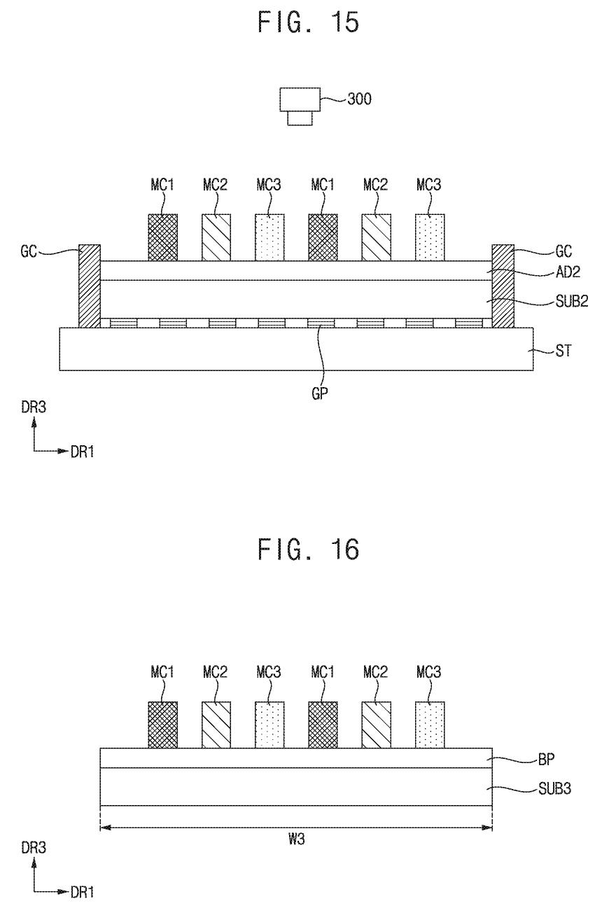

Referring to FIG. 14, the second chucks GC may move in any direction on the plane defined by the first direction DR1 and the second direction DR2. For example, the second chucks GC may move toward the second substrate SUB2. Accordingly, the second chucks GC may be arranged in close contact with the second substrate SUB2. For example, the second chucks GC may contact a side surface of the second substrate SUB2. Accordingly, the second chucks GC may fix the second substrate SUB2. For example, the second chucks GC may fix a position of the second substrate SUB2 on the stage ST. In addition, the second chucks GC may fix the second substrate SUB2 so that the second substrate SUB2 does not rotate on the stage ST. Accordingly, the camera (e.g., the camera 300 of FIG. 15) may image the second substrate SUB2, the first microchips MC1, the second microchips MC2, and the third microchips MC3 suitably and without error.

Referring to FIG. 15, the camera 300 may image the second substrate SUB2. For example, the camera 300 may image the first microchips MC1, the second microchips MC2, and the third microchips MC3 located on the second substrate SUB2. Through the camera 300, it may be determined whether the first microchips MC1, the second microchips MC2, and the third microchips MC3 are damaged, whether the first microchips MC1, the second microchips MC2, and the third microchips MC3 are properly transferred onto the second substrate SUB2, and how the first microchips MC1, the second microchips MC2, and the third microchips MC3 are arranged. For example, the camera 300 may acquire visual information about the first microchips MC1, the second microchips MC2, and the third microchips MC3.

After acquiring visual information about the first microchips MC1, the second microchips MC2, and the third microchips MC3 through the camera 300, the second substrate SUB2 may be unloaded from the stage assembly by using the second loading/unloading unit. For example, the second substrate SUB2, the second adhesive layer AD2, the first microchips MC1, the second microchips MC2, and the third microchips MC3 may be unloaded from the stage assembly by using the second loading/unloading unit.

Referring to FIG. 16, each of the first microchips MC1, the second microchips MC2, and the third microchips MC3 may be transferred from the second substrate (e.g., the second substrate SUB2 of FIG. 15) onto a third substrate SUB3. For example, a circuit layer BP may be formed on the third substrate SUB3, and each of the first microchips MC1, the second microchips MC2, and the third microchips MC3 may be transferred onto the circuit layer BP. The circuit layer BP may include pixel circuit-driving portions. Each of the pixel circuit-driving portions may include a transistor and a capacitor. Each of the pixel circuit-driving portions may be electrically connected to a corresponding one of the first microchips MC1, the second microchips MC2, and the third microchips MC3.

Referring to FIG. 17, the third substrate SUB3 may be located (or, seated) on the stage assembly. In embodiments, the third substrate SUB3 may include a polyimide substrate, a quartz substrate (e.g., a synthetic quartz substrate, a fluorine-doped quartz substrate, and/or the like), a calcium fluoride substrate, a soda lime glass substrate, a non-alkali glass substrate, and/or the like. These materials may be used alone or in combination with each other. As described with reference to FIG. 2, the substrate loaded to the stage assembly by the second loading/unloading unit (e.g., the second loading/unloading unit 200 of FIG. 2) may include a polyimide substrate, a quartz substrate (e.g., a synthetic quartz substrate, a fluorine-doped quartz substrate, and/or the like), a calcium fluoride substrate, a soda lime glass substrate, a non-alkali glass substrate, and/or the like. Accordingly, the third substrate SUB3 may be loaded to the stage assembly by the second loading/unloading unit.

In embodiments, the third substrate SUB3 may be located (or, seated) on the second pins GP. For example, after the second pins GP move up (or, move in the third direction DR3), the third substrate SUB3 may be located (or, seated) on the second pins GP. For example, the third substrate SUB3, the circuit layer BP, the first microchips MC1, the second microchips MC2, and the third microchips MC3 may be located (or, seated) on the second pins GP.

Referring to FIG. 18, the second pins GP may guide a movement of the third substrate SUB3. For example, the second pins GP may guide a downward movement of the third substrate SUB3. As described above, the second pins GP may move down (or, move in a direction opposite to the third direction DR3). As the second pins GP move down, the third substrate SUB3, the circuit layer BP, the first microchips MC1, the second microchips MC2, and the third microchips MC3 located (or, seated) on the second pins GP, may move down.

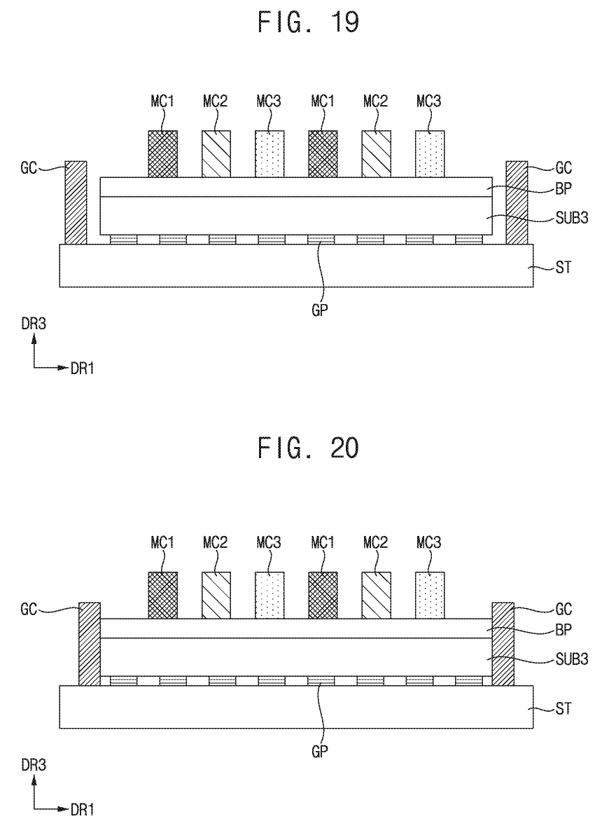

Referring to FIG. 19, the second chucks GC may move up (or, move in the third direction DR3).

Referring to FIG. 20, the second chucks GC may move in any direction on the plane defined by the first direction DR1 and the second direction DR2. For example, the second chucks GC may move toward the third substrate SUB3. Accordingly, the second chucks GC may be arranged in close contact with the third substrate SUB3. For example, the second chucks GC may contact a side surface of the third substrate SUB3. Accordingly, the second chucks GC may fix the third substrate SUB3. For example, the second chucks GC may fix a position of the third substrate SUB3 on the stage ST. In addition, the second chucks GC may fix the third substrate SUB3 so that the third substrate SUB3 does not rotate on the stage ST. Accordingly, the camera (e.g., the camera 300 of FIG. 15) may image the third substrate SUB3, the circuit layer BP, the first microchips MC1, the second microchips MC2, and the third microchips MC3 suitably and without error.

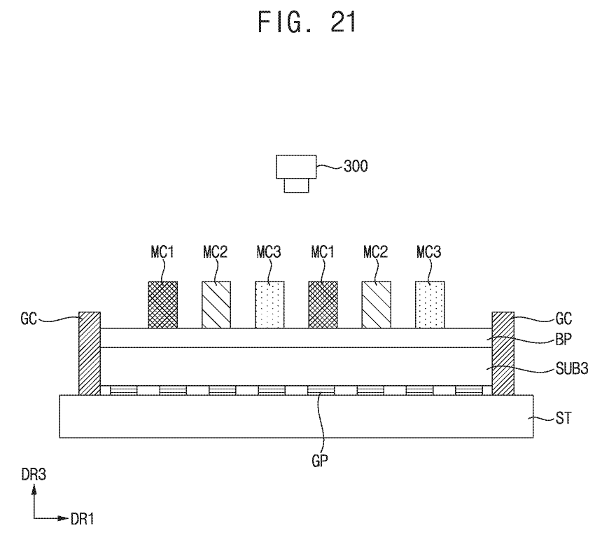

Referring to FIG. 21, the camera 300 may image the third substrate SUB3. For example, the camera 300 may image the circuit layer BP located on the third substrate SUB3.

For example, the camera 300 may image the first microchips MC1, the second microchips MC2, and the third microchips MC3 located on the circuit layer BP. Through the camera 300, it may be determined whether the first microchips MC1, the second microchips MC2, and/or the third microchips MC3 are damaged, whether the first microchips MC1, the second microchips MC2, and/or the third microchips MC3 are properly transferred onto the circuit layer BP, and how the first microchips MC1, the second microchips MC2, and/or the third microchips MC3 are arranged. For example, the camera 300 may acquire visual information about the first microchips MC1, the second microchips MC2, and/or the third microchips MC3.

After acquiring visual information about the first microchips MC1, the second microchips MC2, and/or the third microchips MC3 through the camera 300, the third substrate SUB3 may be unloaded from the stage assembly by using the second loading/unloading unit. For example, the third substrate SUB3, the circuit layer BP, the first microchips MC1, the second microchips MC2, and the third microchips MC3 may be unloaded from the stage assembly by using the second loading/unloading unit.

Referring to FIGS. 2, 4, 10, and 16, in embodiments, a width W1 of the first substrate SUB1 in the first direction DR1 may be less than a width W2 of the second substrate SUB2 in the first direction DR1. In addition, a width of the first substrate SUB1 in the second direction DR2 may be less than a width of the second substrate SUB2 in the second direction DR2. In embodiments, the width W1 of the first substrate SUB1 in the first direction DR1 may be less than a width W3 of the third substrate SUB3 in the first direction DR1. In addition, the width of the first substrate SUB1 in the second direction DR2 may be less than a width of the third substrate SUB3 in the second direction DR2.

The first pins WP repeatedly arranged in the first area A1 may guide the downward movement of the first substrate SUB1, which has a smaller width in the first direction DR1 and the second direction DR2 than the second substrate SUB2 (or, the third substrate SUB3). For example, the second pins GP repeatedly arranged in the second area A2 may guide the downward movement of the second substrate SUB2 (or, the third substrate SUB3), which has a larger width in the first direction DR1 and the second direction DR2 than the first substrate SUB1.

As described above, the separation distance AL1 in the plan view between the first chucks overlapping each other in the first direction DR1 among the first chucks WC may be less than the separation distance AL2 in the plan view between the second chucks overlapping each other in the first direction DR1 among the second chucks GC. The first chucks WC may fix the first substrate SUB1, which has a smaller width in the first direction DR1 and the second direction DR2 than the second substrate SUB2 (or, the third substrate SUB3). For example, the second chucks GC may fix the second substrate SUB2 (or, the third substrate SUB3), which has a larger width in the first direction DR1 and the second direction DR2 than the first substrate SUB1.

The stage assembly SA may include the first pins WP and the second pins GP. Accordingly, the first substrate SUB1 and the second substrate SUB2 (or, the third substrate SUB3), which have different widths, may be located (or, seated) on a single stage assembly SA. For example, the first substrate SUB1 and the second substrate SUB2 (or, the third substrate SUB3), which have different widths in the first direction DR1 and the second direction DR2, may be located (or, seated) on a single stage assembly SA. In addition, as the stage assembly SA includes the first pins WP and the second pins GP, the single stage assembly SA may guide the downward movement of the first substrate SUB1 and the second substrate SUB2 (or, the third substrate SUB3), which have different widths in the first direction DR1 and the second direction DR2.

The stage assembly SA may include the first chucks WC and the second chucks GC. Accordingly, the single stage assembly SA may fix the first substrate SUB1 and the second substrate SUB2 (or, the third substrate SUB3), which have different widths in the first direction DR1 and the second direction DR2. For example, the single stage assembly SA may fix the positions of the first substrate SUB1 and the second substrate SUB2 (or, the third substrate SUB3), which have different widths in the first direction DR1 and the second direction DR2, and may fix the first substrate SUB1 and the second substrate SUB2 (or, the third substrate SUB3) to reduce or prevent the likelihood of them from rotating on the stage ST.

As described above, the first substrate SUB1 may include a semiconductor wafer substrate, and each of the second substrate SUB2 and the third substrate SUB3 may include a polyimide substrate, a quartz substrate (e.g., a synthetic quartz substrate, a fluorine-doped quartz substrate, and/or the like), a calcium fluoride substrate, a soda-lime glass substrate, a non-alkali glass substrate, and/or the like.

As the stage assembly SA includes the first pins WP and the second pins GP, the single stage assembly SA may guide the downward movement of the first substrate SUB1 and the second substrate SUB2 (or, the third substrate SUB3), which include different respective materials.

As the stage assembly SA includes the first chucks WC and the second chucks GC, the single stage assembly SA may fix the first substrate SUB1 and the second substrate SUB2 (or, the third substrate SUB3), which include different respective materials.

In summary, regardless of materials included in the substrate located (or, seated) on the stage assembly SA or a width of the substrate, a single stage assembly SA may be used to inspect a target object. For example, regardless of the materials included in the substrate located (or, seated) on the stage assembly SA or the width of the substrate, a single stage assembly SA may be used to inspect microchips. Accordingly, a configuration of the inspection apparatus (e.g., the inspection apparatus 1000 of FIG. 1) may be simplified. In addition, time and cost suitable to inspect the target object may be reduced. For example, time and cost suitable to inspect the microchips may be reduced.

The present disclosure can be applied to various inspection apparatuses. For example, the present disclosure is applicable to various inspection apparatuses such as automatic optical inspection apparatuses, and/or the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims, with functional equivalents thereof to be included therein.

What is claimed is:

1. A stage assembly comprising:
a stage;
a first pin above the stage, the first pin being configured to guide movement of a first substrate; and
a second pin above the stage and spaced apart from the first pin in a plan view, the second pin being configured to guide movement of a second substrate.

2. The stage assembly of claim 1, wherein the first pin is configured to guide a downward movement of the first substrate, and
wherein the second pin is configured to guide a downward movement of the second substrate.

3. The stage assembly of claim 1, wherein a width of the first substrate in a first direction is less than a width of the second substrate in the first direction.

4. The stage assembly of claim 1, wherein the first substrate comprises a semiconductor wafer substrate, and
wherein the second substrate comprises a polyimide substrate, a quartz substrate, a calcium fluoride substrate, a sodalime glass substrate, or a non-alkali glass substrate.

5. The stage assembly of claim 1, wherein the first pin is repeatedly arranged in a first area, and
wherein the second pin is repeatedly arranged in a second area having a width in a first direction that is greater than a width of the first area in the first direction.

6. The stage assembly of claim 1, further comprising:
a first chuck configured to fix the first substrate; and
a second chuck configured to fix the second substrate and spaced apart from the first chuck in the plan view.

7. The stage assembly of claim 6, wherein the first chuck and the second chuck are configured to be moved in a vertical direction and in a horizontal direction.

8. The stage assembly of claim 6, wherein the first chuck is provided in plural,
wherein the second chuck is provided in plural, and
wherein a distance between adjacent ones of the first chucks overlapping with each other in a first direction is less than a distance between adjacent ones of the second chucks overlapping with each other in the first direction.

9. An inspection apparatus comprising:
a first loading/unloading unit configured to load a first substrate to a stage and to unload the first substrate from the stage;
a second loading/unloading unit configured to load a second substrate to the stage and to unload the second substrate from the stage;
a first pin above the stage and configured to guide movement of the first substrate; and
a second pin above the stage, spaced apart from the first pin in a plan view, and configured to guide movement of the second substrate.

10. The inspection apparatus of claim 9, further comprising a camera configured to image a microchip transferred from a growth substrate onto the first substrate and to image the microchip transferred from the first substrate onto the second substrate.

11. The inspection apparatus of claim 9, wherein a width of the first substrate in a first direction is less than a width of the second substrate in the first direction.

12. The inspection apparatus of claim 9, wherein the first substrate comprises a semiconductor wafer substrate, and
wherein the second substrate comprises a polyimide substrate, a quartz substrate, a calcium fluoride substrate, a sodalime glass substrate, or a non-alkali glass substrate.

13. The inspection apparatus of claim 9, wherein the first pin is repeatedly arranged in a first area,
wherein the second pin is repeatedly arranged in a second area, and
wherein a width of the first area in a first direction is less than a width of the second area in the first direction.

14. The inspection apparatus of claim 9, further comprising:
a first chuck configured to fix the first substrate; and
a second chuck configured to fix the second substrate and spaced apart from the first chuck in the plan view.

15. The inspection apparatus of claim 14, wherein the first chuck and the second chuck are configured to be moved in a vertical direction and in a horizontal direction.

16. The inspection apparatus of claim 14, wherein the first chuck is provided in plural,
wherein the second chuck is provided in plural, and
wherein a distance between adjacent ones of the first chucks overlapping with each other in a first direction is less than a distance between adjacent ones of the second chucks overlapping with each other in the first direction.

17. An inspection method comprising:
transferring a microchip from a growth substrate onto a first substrate;
placing the first substrate on a first pin above a stage;
lowering the first pin and the first substrate;
capturing one or more images of the first substrate and the microchip;
transferring the microchip from the first substrate onto a second substrate;
placing the second substrate on a second pin above the stage and spaced apart from the first pin in a plan view;
lowering the second pin and the second substrate; and
capturing one or more images of the second substrate and the microchip.

18. The inspection method of claim 17, wherein a width of the first substrate in a first direction is less than a width of the second substrate in the first direction.

19. The inspection method of claim 17, wherein the first substrate comprises a semiconductor wafer substrate, and
wherein the second substrate comprises a polyimide substrate, a quartz substrate, a calcium fluoride substrate, a sodalime glass substrate, or a non-alkali glass substrate.

20. The inspection method of claim 17, further comprising:
moving a first chuck toward the first substrate to fix the first substrate; and
moving a second chuck, spaced apart from the first chuck in the plan view, toward the second substrate to fix the second substrate.
